(19) United States
(12) Patent Application Publication
(10) Pub. No.: US 2007/0069213 A1
(43) Pub. Date: Mar. 29, 2007

(54) Flexible adjustment of on-die termination values in semiconductor device

(76) Inventors: Woo-Jin Lee, Seongnam-si (KR); Kwang-Il Park, Yongin-si (KR); Hyun-Jin Kim, Suwon-si (KR)

Correspondence Address: LAW OFFICE OF MONICA H CHOI, P O BOX 3424, DUBLIN, OH, 430160204, US

(21) Appl. No.: 11/475,668

(22) Filed: Jun. 27, 2006

(30) Foreign Application Priority Data
Jun. 27, 2005 (KR) 2005-55887

(51) Int. Cl. H01L 27/108; H01L 29/00; H01L 31/036; H01L 31/112

(52) U.S. Cl. 257/68

(57) ABSTRACT

A termination value for a pin of a semiconductor device is set to a first value if a pin signal has a first logic state at an edge of a control signal, and to a second value if the pin signal has a second logic state at the edge of the control signal. Alternatively, a respective logic state of a first control signal is determined at an edge of a second control signal, and a respective logic state of the pin signal is determined at the edge of the second control signal. The termination value is set depending on such respective logic states.

### BACKGROUND OF THE INVENTION

This application claims priority to Korean Patent Application No. 2005-55887, filed on Jun. 27, 2005 in the Korean Intellectual Property Office, the disclosure of which is incorporated herein in its entirety by reference.

1. Field of the Invention

The present invention relates generally to semiconductor devices such as semiconductor memory devices, and more particularly, to being able to flexibly adjust on-die termination values for pins of the semiconductor device.

2. Description of the Related Art

Transmission lines are an important consideration in designing and implementing electronic systems. Due to unwanted phenomena such as signal reflection, signals transmitted through transmission lines may oscillate above and below logic high and logic low states. Signal reflection is caused by impedance mismatch between drivers, receivers, or transmission lines.

Termination enhances signal integrity and bandwidth by minimizing signal reflection in transmission lines. FIG. 1 illustrates a conventional system 100 including a plurality of devices 110a, 110b, 110c, 110d, and 110e, each having a respective termination circuit 120. In addition, each of the devices 110a, 110b, 110c, 110d, and 110e includes a respective transmission driver 112, a respective reception driver 114, and the respective termination circuit 120.

The transmission driver 112 is controlled by a driver enable signal DRIVER ENABLE and transmits a transmission signal DRIVER SIGNAL to a bus 102. The reception driver 114 is controlled by a reception enable signal RECEIVER ENABLE and receives a reception signal RECEIVED SIGNAL from the bus 102. The termination circuit 120 includes a switch 122 coupled in series with a trimmable termination resistor 124. The switch 122 is also coupled to a termination voltage supply proving a voltage VTERM, and is controlled by a termination enable signal TERMINATION ENABLE.

The resistance of the termination resistor 124 is trimmed in a calibration process that determines an optimal termination value (i.e., termination resistance value) of the bus 102. For a memory device such as a dynamic random access memory (DRAM) device, the trimming for the termination resistor 124 occurs in a power-up and initialization process.

In addition, the termination value should be adjusted according to the configuration of multiple devices in a system. FIG. 2 illustrates an example configuration of two devices 110a and 110b sharing an address/command line. Generally, a data line is connected to each of the devices 110a and 110b as a separate line such that the termination value for a data line is not adjusted according to a configuration of the system.

However, referring to FIG. 2, the address/command line is shared by the devices 110a and 110b. The effective resistance at the address/command line depends on which of the devices 110a and 110 is coupled to the address/command line for operation. If just the device 110a is coupled to the address/command line for operation, the effective resistance at the address/command line is from the two resistors R1 and R2 being connected to the address/command line in parallel.

On the other hand, if just the device 110b is coupled to the address/command line for operation, the effective resistance at the address/command line is from the two resistors R3 and R4 being connected to the address/command line in parallel. If both the devices 110a and 110b are coupled to the address/command line for operation, then the effective resistance at the address/command line is from the four resistors R1, R2, R3, and R4 being connected to the address/command line in parallel. Thus, for maintaining a constant effective resistance at the address/command line in FIG. 2, the resistance of each of the resistors R1, R2, R3, and R4 is desired to be varied depending on the configuration of the system of FIG. 2.

Generally, termination values for address/command pins in a memory device such as a DRAM device are adjusted depending on a phase relationship of a reset signal RESET and a clock signal CKE in a power-up sequence. Such signals RESET and CKE are control signals that are applied on pins different from the address/command pins. For example, if the phase of the reset signal RESET is delayed from that of the clock signal CKE during the power-up sequence, the termination values of all address/command pins are set to a first value ZQ.

On the other hand, if the phase of the reset signal RESET is advanced from that of the clock signal CKE, the termination values of all address/command pins are set to a second value ZQ/2. Such phase relationships may be determined by a logic state of the clock signal CKE that is latched at a rising edge of the reset signal RESET.

With advancement of memory systems, some address/command pins of a memory device in a memory system are driven from separate lines while other address/command pins are shared with another memory device. Thus, termination values need to be adjusted differently depending on the configuration of the address/command pins. However, comparing the phases of the reset and clock signals RESET and CKE in the prior art is for uniformly setting the termination values of all address/command pins.

Rather, an extended mode register set (EMRS) is used in the prior art for separately adjusting termination values for a sub-set of address/command pins. FIG. 3 shows a table of example EMRS codes A [2:0] for indicating such a sub-set of address/command pins during the power-up sequence of a memory device. For example, if A [2:0] is ‘000’, none of the address/command pins are separately adjusted.

Alternatively if A [2:0] is ‘001’, the A [2] address pin is in such a sub-set for separate adjustment of the termination value. If A [2:0] is ‘010’, A [3:2] are the address pins in such a sub-set. If A [2:0] is ‘011’, A [4:2] are the address pins in such a subset. If A [2:0] is ‘100’, A [5:2] are the address pins in such a subset. If A [2:0] is ‘101’, A [6:2] are the address pins in such a subset. If A [2:0] is ‘110’, A [7:2] are the address pins in such a subset. If A [2:0] is ‘111’, A [9, 7:2] are the address pins in such a subset.

FIG. 4 is a block diagram of a conventional memory device 40 having components for separate termination adjustment using the EMRS code A [2:0] of FIG. 3. A mode register 43 stores the EMRS code A [2:0] that is decoded by a decoder 44. The memory device 40 also includes a plurality of ODT (on-die-termination) controllers 41_0, 41_1, . . . , and 41_n corresponding to n address pins A0, A1, . . . , and An, respectively. The memory device 40 further includes a CKE (clock) latch unit 42.

The CKE latch unit 42 latches the clock signal CKE at a rising edge of the reset signal RESET to output such a latched clock signal to each of the ODT controllers 41_0, 41_1, . . . , and 41_n. The decoder 44 decodes the EMRS code from the mode register 43 and sends control signals indicating which of the address pins A0 A1, . . . , and An is in the subset having the termination values separately adjusted.

For example, assume that the clock signal CKE has a logic high state at the rising edge of the reset signal RESET and the EMRS code is ‘010’. Further in such an example, the termination values of the pins for the addresses A [3:2] are each adjusted to a first value while the termination values of the address pins corresponding to the remaining addresses A [n;4, 1, 0] are each adjusted to a second value.

However, use of such an EMRS code for indicating the sub-set of address pins is disadvantageous because the EMRS code may not be sufficient for indicating every possible sub-set of address pins. In addition, when a board configuration of a memory system is changed, the EMRS code is difficult to change for varying the sub-sets of address pins to be separately adjusted.

### SUMMARY OF THE INVENTION

Accordingly, embodiments of the present invention provide more flexible adjustment of a termination value for a pin of a semiconductor device by using a pin signal applied at such a pin.

For determining a termination value for a pin of a semiconductor device according to one aspect of the present invention, the termination value is set to a first value if a pin signal applied on the pin has a first logic state at an edge of a control signal. The termination value is set to a second value if the pin signal has a second logic state at the edge of the control signal.

In an example embodiment of the present invention, the pin signal is an address signal, and the control signal is a reset signal.

In another embodiment of the present invention, the termination value is set during a power-up or initialization process of the semiconductor device.

In a further embodiment of the present invention, the first value is higher than the second value when a phase relationship between the control signal and the pin signal indicates that the pin is coupled to at least one other memory device. The phase relationship is set by a processor of the semiconductor device.

For determining a termination value for a pin of a semiconductor device according to another aspect of the present invention, a respective logic state of a first control signal is determined at an edge of a second control signal. In addition, a respective logic state of a pin signal is determined at the edge of the second control signal with the pin signal being applied on the pin. The termination value is set depending on such respective logic states.

In one example embodiment of the present invention, the pin signal is an address signal; the first control signal is a clock signal; and the second control signal is a reset signal.

In another embodiment of the present invention, the termination value when a phase relationship between the control signal and the pin signal indicates that the pin is coupled to at least one other memory device is higher than the termination value when the phase relationship indicates that the pin is coupled to only one memory device. The phase relationship is set by a processor of the semiconductor device.

In this manner, the individual pin signal applied on a pin is used for adjusting the termination value for the pin. Thus, by varying such a pin signal, the termination value for each pin is flexibly adjusted.

### BRIEF DESCRIPTION OF THE DRAWINGS

The above and other features and advantages of the present invention will become more apparent when described in detailed exemplary embodiments thereof with reference to the attached drawings in which:

FIG. 1 shows a conventional system with a plurality of devices, each having a respective termination circuit;

FIG. 2 illustrates variation of effective resistance at an address/command line depending on which devices coupled thereto are operating, as known in the prior art;

FIG. 3 shows a table of example EMRS codes for indicating a subset of pins having termination values adjusted separately, according to the prior art;

FIG. 4 is a block diagram of a conventional memory device that uses the EMRS code of FIG. 3, according to the prior art;

FIG. 5 is a block diagram of a memory device that uses a pin signal on a pin for flexible adjustment of the termination value, according to an embodiment of the present invention;

FIGS. 6A and 6B are example timing diagrams of a clock signal latched to a reset signal, according to an embodiment of the present invention;

FIGS. 7A and 7B are example timing diagrams of address pin signals latched to the reset signal, according to an embodiment of the present invention;

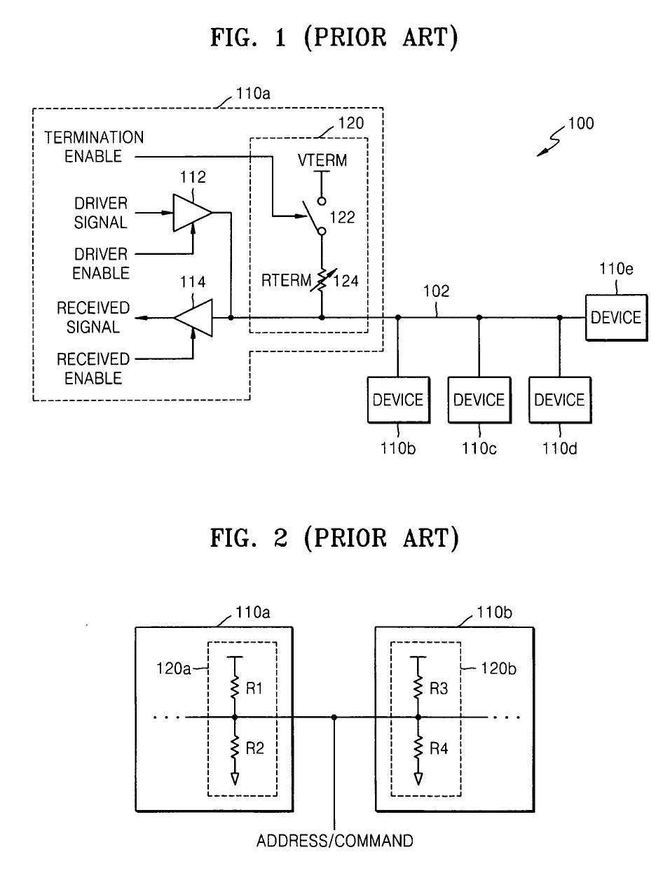

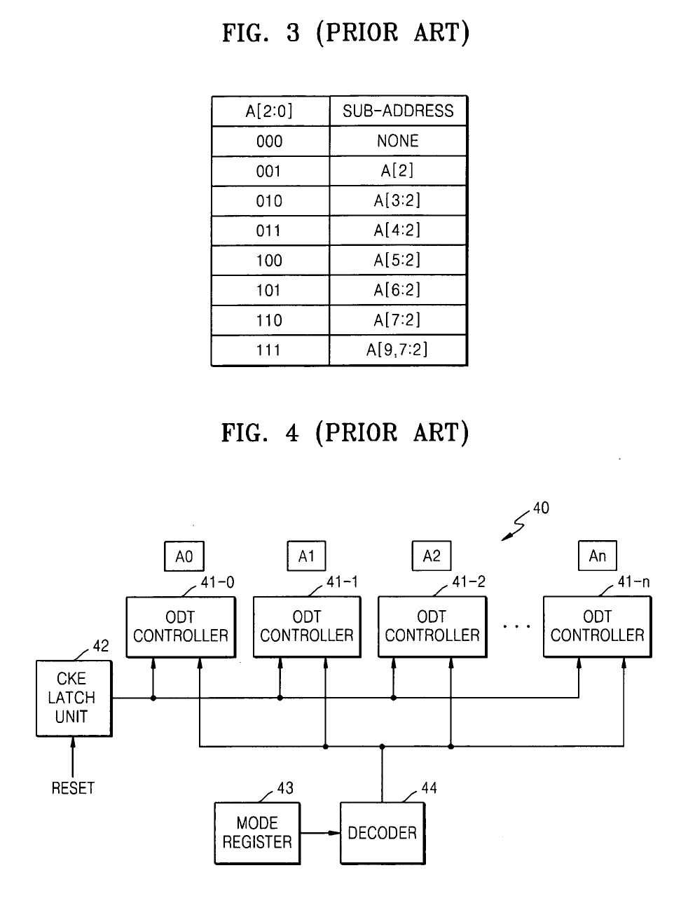

The figures referred to herein are drawn for clarity of illustration and are not necessarily drawn to scale. Elements having the same reference number in FIGS. 1, 2, 3, 4, 5, 6 and 7 refer to elements having similar structure and/or function.

### DETAILED DESCRIPTION OF THE INVENTION

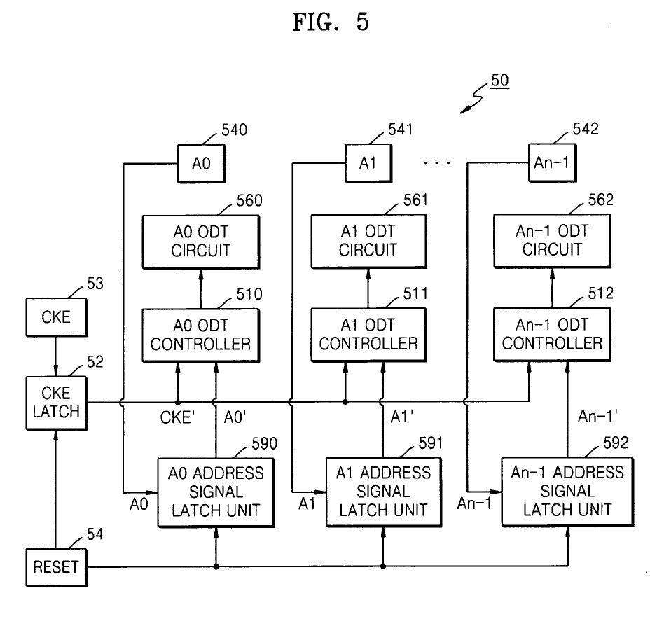

FIG. 5 is a block diagram of a memory device 50 that uses a pin signal on a pin for flexible adjustment of a termination value (i.e., a termination resistance value) for the pin, according to an embodiment of the present invention. The present invention is described for the memory device 50 as an example semiconductor device. However, the present invention may be applied for any type of semiconductor device.

Referring to FIG. 5, the memory device 50 has a plurality of pins including a first address pin 540, a second address pin 541, and so on up to an n-th address pin 542. Each of the address pins 540, 541, . . . , and 542 has a respective address signal A0, A1, . . . , and An-1 applied thereon. The term pin as used herein is broadly defined as any node in a semiconductor device coupled to a transmission line and thus desiring adjustment of the termination value for the pin such that impedance mismatch is minimized. Each of the address signals A0, A1, . . . , and An-1 is a pin signal applied at a respective pin needing setting of a respective termination value.

Further referring to FIG. 5, the memory device 50 includes a clock pin 53 having a clock signal CKE applied thereon and includes a reset pin 54 having a reset signal RESET applied thereon. The clock and reset signals CKE and RESET are each a control signal. A control signal is defined herein as a signal that is applied on another pin that is separate from the pin needing setting of a respective termination value.

The memory device 50 also includes a first on-die-termination (ODT) circuit 560, a second ODT circuit 561, . . . , and an n-th ODT circuit 562, each generating a respective impedance with a respective termination value at a corresponding one of the pins 540, 541, . . . , and 542. The memory device 50 additionally includes a first on-die-termination (ODT) controllers 510, a second ODT controller 511, . . . , and an n-th ODT controller 512, each controlling a corresponding one of the ODT circuits 560, 561, . . . , and 562.

The memory device 50 further includes a clock (CKE) latch 52 that generates a latched clock signal CKE′ from the clock signal CKE and the reset signal RESET. The latched clock signal CKE′ indicates a phase relationship between the clock and reset signals CKE and RESET.

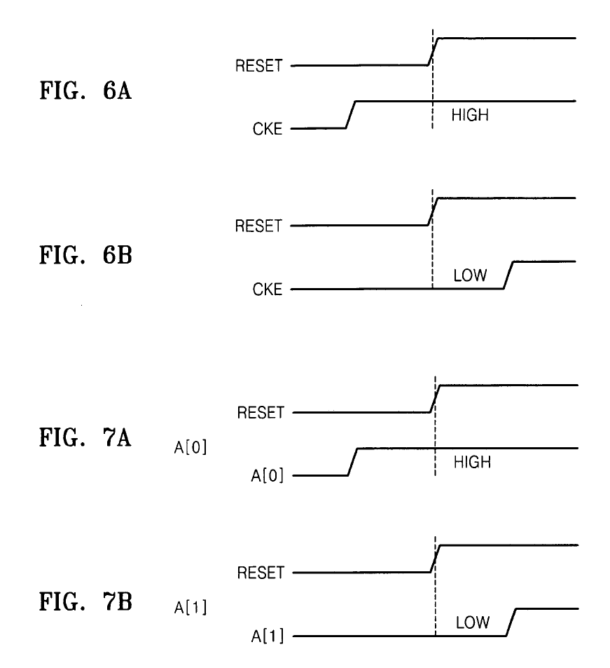

For example, the CKE latch unit 52 latches the clock signal CKE at a rising edge of the reset signal RESET to generate the latched clock signal CKE′. In that case for the example of FIG. 6A, the phase of the clock signal CKE is delayed from the phase of the reset signal RESET such that the latched clock signal CKE′ is activated to the logic high state. Alternatively for the example of FIG. 6B, the phase of the clock signal CKE is advanced from the phase of the reset signal RESET such that the latched clock signal CKE′ is deactivated to the logic low state. The latched clock signal CKE′ is transmitted to each of the ODT controllers 510, 511, . . . , and 512.

In addition, the memory device 50 includes a first address pin signal latch 590, a second address pin signal latch 591, . . . , and an n-th address pin signal latch 592, each generating a respective one of latched address signals A0′, A1′, . . . , and An-1′ to a respective one of the first ODT controllers 510, the second ODT controller 511, . . . , and the n-th ODT controller 512. Each of the address pin signal latches 590, 591, . . . , and 592 latches a corresponding one of the address pin signals A0, A1, . . . and An-1 to generated a corresponding one of the latched address pin signals A0′, A1′, . . . , and An-1′. Each of the latched pin signals A0′, A1′, . . . , and An-1′indicates a phase relationship between a corresponding one of the address pin signals A0, A1, . . . , and An-1 and the reset signal RESET.

For example in FIG. 7A, the phase of the address pin signal A0 is delayed from the phase of the reset signal RESET. In that case, the pin signal latch 590 latches a logic high state as the latched pin signal A0′ at the rising edge of the reset signal RESET.

Alternatively in the example of FIG. 7B, the phase of the address pin signal A1 is advanced from the phase of the reset signal RESET. In that case, the pin signal latch 591 latches a logic low state as the latched pin signal A1′ at the rising edge of the reset signal RESET. Each of such latched pin signals A0′, A1′, . . . , and An-1′ is transmitted to a corresponding one of the ODT controllers 510, 511, . . . , and 512. Referring to FIGS. 5, 6 and 7, each of the ODT controllers 510, 511, . . . , and 512 controls a corresponding one of ODT circuits 560, 561, . . . , and 562 to generate a respective termination value depending on the logic states of the latched clock signal CKE′ and a corresponding one of the latched address pin signals A0′, A1′, . . . , and An-1′.

Concretely, the respective ODT controllers 510, 511, . . . , 512 control a corresponding one of the ODT circuits 560, 561, . . . , and 562 to generate a higher respective termination value from such a phase relationship that indicates that the address pin is coupled to at least one other memory device.

For example, if the latched clock signal CKE′ is set to the logic high state, the ODT controllers 510, 511, . . . , 512 set the respective termination values for all of the pins 540, 541, . . . , and 542 that are not coupled to any other memory devices to a first value. Alternatively, if the latched clock signal CKE′ is set to the logic low state, the ODT controllers 510, 511, . . . , 512 set the respective termination values for all of the pins 540, 541, . . . , and 542 that are coupled to at least one other memory device to a second value that is twice the first value.

In addition, if any of the latched pin signals A0′, A1′, . . . , An-1′ has a logic high state, the corresponding termination value is further adjusted. In that case, a corresponding one of the pins 540, 541, . . . , and 542 is coupled to more memory devices than the other pins. Thus, the respective termination value may be further increased for impedance matching. In general, when a pin is coupled to a higher number of other memory devices, the respective termination value is further increased for impedance matching.

In any case, the respective termination value for each of the address pins 540, 541, . . . , and 542 may be flexibly controlled depending on logic states of the latched clock signal CKE′ and the latched pin signals A0′, A1′, . . . , An-1′. The foregoing is by way of example only and is not intended to be limiting. For example, any numbers or number of elements described and illustrated herein is by way of example only. In addition, the present invention has been described for a memory device 50. However, the present invention may be practiced for any type of semiconductor device. Furthermore, the present invention has been described for address pins. However, the present invention may be used for setting a respective termination value for a pin having any type of signal applied thereon. The present invention is limited only as defined in the following claims and equivalents thereof.

What is claimed is:

1. A method of determining a termination value for a pin of a semiconductor device, the method comprising:
setting the termination value to a first value if a pin signal applied on the pin has a first logic state at an edge of a control signal; and
setting the termination value to a second value if the pin signal has a second logic state at the edge of the control signal.

2. The method of claim 1, wherein the pin signal is an address signal, and wherein the control signal is a reset signal.

3. The method of claim 1, wherein the termination value is set during a power-up or initialization process of the semiconductor device.

4. The method of claim 1, wherein the first value is higher than the second value when a phase relationship between the control signal and the pin signal indicates that the pin is coupled to at least one other memory device.

5. The method of claim 4, wherein the phase relationship is set by a processor of the semiconductor device.

6. A method of determining a termination value for a pin of a semiconductor device, the method comprising:
determining a respective logic state of a first control signal at an edge of a second control signal;
determining a respective logic state of a pin signal at the edge of the second control signal with the pin signal being applied on the pin; and
setting the termination value depending on the respective logic states.

7. The method of claim 6, wherein the pin signal is an address signal, and wherein the first control signal is a clock signal, and wherein the second control signal is a reset signal.

8. The method of claim 6, wherein the termination value is set during a power-up or initialization process of the semiconductor device.

9. The method of claim 6, wherein the termination value when a phase relationship between the control signal and the pin signal indicates that the pin is coupled to at least one other memory device is higher than the termination value when the phase relationship indicates that the pin is coupled to only one memory device.

10. The method of claim 9, wherein the phase relationship is set by a processor of the semiconductor device.

11. A semiconductor device comprising:
a pin signal latch for determining a logic state of a pin signal applied on a pin of the semiconductor device at an edge of a control signal; and
an on-die termination controller that sets a termination value for said pin to a first value if the logic state is a first logic state, and to a second value if the logic state is a second logic state.

12. The semiconductor device of claim 11, wherein the pin signal is an address signal, and wherein the control signal is a reset signal.

13. The semiconductor device of claim 11, wherein the termination value is set during a power-up or initialization process of the semiconductor device.

14. The semiconductor device of claim 11, wherein the first value is higher than the second value when a phase relationship between the control signal and the pin signal indicates that the pin is coupled to at least one other memory device.

15. The semiconductor device of claim 14, wherein the phase relationship is set by a processor of the semiconductor device.

16. A semiconductor device, comprising:
a control signal latch for determining a respective logic state of a first control signal at an edge of a second control signal;
a pin signal latch for determining a respective logic state of a pin signal at the edge of the second control signal with the pin signal being applied on a pin of the semiconductor device; and
an on-die termination controller for setting a termination value for the pin depending on the respective logic states as determined by the latches.

17. The semiconductor device of claim 16, wherein the pin signal is an address signal, and wherein the first control signal is a clock signal, and wherein the second control signal is a reset signal.

18. The semiconductor device of claim 16, wherein the termination value is set during a power-up or initialization process of the semiconductor device.

19. The semiconductor device claim 16, wherein the termination value when a phase relationship between the control signal and the pin signal indicates that the pin is coupled to at least one other memory device is higher than the termination value when the phase relationship indicates that the pin is coupled to only one memory device.

20. The semiconductor device of claim 19, wherein the phase relationship is set by a processor of the semiconductor device.
